(19) United States
(12) Patent Application Publication
(10) Pub. No.: US 2011/0157964 A1
(43) Pub. Date: Jun. 30, 2011

(54) Memory Cell Using Leakage Current Storage Mechanism

(76) Inventors: Richard J. McPartland, Nazareth, PA (US); Hai Quang Pham, Hatfield, PA (US); Wayne E. Werner, Coopersburg, PA (US)

(21) Appl. No.: 12/649,847

(22) Filed: Dec. 30, 2009

(51) Int. Cl. G11C 11/00; G11C 5/14

(52) U.S. Cl. 365/156; 365/226

(57) ABSTRACT

A memory cell comprises a storage element including a transistor and an inverter. The inverter has an input coupled to a first source/drain of the transistor at a first node and has an output coupled to a gate of the transistor at a second node. The transistor has a second source/drain coupled to a voltage supply of the memory circuit. The memory cell further includes a switching element coupled to the storage element at the first node and being operative to selectively access the storage element as a function of a control signal supplied to a control input of the switching element. The storage element is operative to store at least first and second data states. The first data state is retained in the storage element by maintaining the first node at a first voltage level by leakage current and by maintaining the second node at a second voltage level by active current. The second data state is retained in the storage element by maintaining the first node at the second voltage level and the second node at the first voltage level by respective active currents.

### FIELD OF THE INVENTION

The present invention relates generally to the electrical, electronic, and computer arts, and more particularly relates to memory cells.

### BACKGROUND OF THE INVENTION

Power dissipation of an integrated circuit (IC) is composed of active power and leakage power. Leakage power is proportional to leakage current and, typically, serves no useful purpose in most conventional ICs. In recent IC fabrication technologies, leakage currents have increased and become a critical concern. A major source of leakage current is current flowing between the source and drain junctions of a field effect transistor (FET) when the FET is biased in an “off” state. An example is sub-threshold leakage current which flows between the source and drain when the FET is turned off.

Embedded memory, which includes, for example, static random access memory (SRAM), is a major component in modern ICs. SRAM typically comprises many memory cells, for example, millions of memory cells. Leakage current may flow through one or more transistors within each memory cell in the SRAM. As a result, a major component of leakage current within an IC is attributable to leakage current within the individual memory cells.

The cost to fabricate an IC is usually directly proportional to the area of the IC. Therefore, because SRAM and other embedded memory often occupy a significant portion of the overall area of an IC, it is desirable, in order to reduce the cost of the IC, to reduce the size (geometry) of memory cells in the embedded memory. Unfortunately, reducing the geometry of the memory cells often results in increased leakage current in the cells, which has been conventionally disadvantageous.

### SUMMARY OF THE INVENTION

Principles of the invention, in illustrative embodiments thereof, provide memory cells adapted to store data maintained at least partially by the flow of leakage current in the cells. Memory cells, memories and integrated circuits which store data maintained at least partially by the flow of leakage current are provided.

In accordance with one embodiment of the invention, a memory cell comprises a storage element including a transistor and an inverter. The inverter has an input coupled to a first source/drain of the transistor at a first node and has an output coupled to a gate of the transistor at a second node. The transistor has a second source/drain coupled to a first voltage supply of the memory circuit. The memory cell further includes a switching element coupled to the storage element at the first node and being operative to selectively access the storage element as a function of a control signal supplied to a control input of the switching element. The storage element is operative to store at least first and second data states. The first data state is retained in the storage element by maintaining the first node at a first voltage level by leakage current and by maintaining the second node at a second voltage level by active current. The second data state is retained in the storage element by maintaining the first node at the second voltage level and the second node at the first voltage level by respective active currents. The memory circuit may be embodied in an IC.

In accordance with another embodiment of the invention, an electronic system includes at least one IC comprising a memory circuit having at least one memory cell. The memory cell includes a storage element including a transistor and an inverter. The inverter has an input coupled to a first source/drain of the transistor at a first node and has an output coupled to a gate of the transistor at a second node. The transistor has a second source/drain coupled to a first voltage supply of the memory circuit. The memory cell further includes a switching element coupled to the storage element at the first node and being operative to selectively access the storage element as a function of a control signal supplied to a control input of the switching element. The storage element is operative to store at least first and second data states. The first data state is retained in the storage element by maintaining the first node at a first voltage level by leakage current and by maintaining the second node at a second voltage level by active current. The second data state is retained in the storage element by maintaining the first node at the second voltage level and the second node at the first voltage level by respective active currents.

Advantages of embodiments of the present invention include, but are not limited to, smaller and less power-consuming memory cells, memories and integrated circuits. Use of techniques of the invention results in, for example, lower cost integrated circuits, higher production capacity (e.g., yield) of integrated circuits, and integrated circuits that are less expensive to operate. Equipment including integrated circuits comprising embodiments of the invention (e.g., embedded or discrete memory) may also be lower in cost and less expensive to operate. An additional advantage of the invention includes, for example, enhanced four-transistor memory cell stability due to maintaining stored data by active current on at least one storage node of the four-transistor memory cell, regardless of the data state being stored therein. This results in a more robust memory cell design which is significantly less susceptible to noise and other undesirable memory disturbs compared to conventional memory cells.

These and other features, objects and advantages of the present invention will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein:

FIG. 1 is a schematic diagram depicting an illustrative six-transistor SRAM cell;

FIG. 2A is a schematic diagram depicting an exemplary four-transistor SRAM cell and corresponding leakage currents flowing through selected transistors in the cell when storing a logic “0” data state, according to an embodiment of the present invention;

FIG. 2B is a schematic diagram depicting the exemplary SRAM cell of FIG. 2A and corresponding leakage currents flowing through selected transistors in the cell when storing a logic “1” data state, according to an embodiment of the present invention;

FIG. 2C is a schematic diagram depicting at least a portion of an exemplary memory circuit including two illustrative four-transistor SRAM cells of the type shown in FIGS. 2A and 2B coupled to a common bitline, according to an embodiment of the present invention;

FIG. 3 is a schematic diagram depicting at least a portion of an exemplary four-transistor SRAM cell, according to another embodiment of the present invention;

FIG. 4 is a schematic diagram depicting at least a portion of an exemplary four-transistor SRAM cell, according to yet another embodiment of the present invention;

FIG. 5 is a schematic diagram depicting at least a portion of an exemplary four-transistor SRAM cell, according to a fourth embodiment of the present invention;

FIG. 6 is a block diagram depicting at least a portion of an exemplary memory circuit, according to an embodiment of the present invention;

FIG. 7 is a block diagram depicting at least a portion of an exemplary IC comprising a plurality of instances of the illustrative memory circuit shown in FIG. 6, according to an embodiment of the present invention; and

FIG. 8 is a partial sectional view depicting an exemplary packaged IC, according to an embodiment of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION OF PREFERRED EMBODIMENTS

Aspects of the present invention will be described herein in the context of illustrative embodiments of a four-transistor (4T) SRAM cell adapted to utilize leakage current as a storage mechanism for reducing a size of the memory cell without significantly impacting performance of the cell. In accordance with other aspects of the invention, an exemplary memory circuit employing a plurality of memory cells and an illustrative method for forming a memory cell according to an embodiment of the invention are also described. It is to be appreciated, however, that the techniques of the present invention are not limited to the specific method and circuits shown and described herein. Rather, embodiments of the invention are directed broadly to techniques for beneficially utilizing leakage current in a memory cell in order to reduce a size of the cell without significantly impacting reliability or performance, or increasing overall current in the memory cell. For this reason, numerous modifications can be made to these embodiments and the results will still be within the scope of the invention. No limitations with respect to the specific embodiments described herein are intended or should be inferred.

Although reference may be made herein to n-channel metal-oxide-semiconductor (NMOS) or p-channel metal-oxide-semiconductor (PMOS) transistor devices which may be formed using a complementary metal-oxide-semiconductor (CMOS) IC fabrication process, the invention is not limited to such devices and/or such an IC fabrication process. Furthermore, although preferred embodiments of the invention may be fabricated in a silicon wafer, embodiments of the invention can alternatively be fabricated in wafers comprising other materials, including but not limited to gallium arsenide (GaAs), indium phosphide (InP), etc.

Aspects of the present invention advantageously provide a memory circuit having improved performance and reliability. The memory circuit may comprise, for example, an embedded memory (e.g., a memory embedded within an IC) or a stand-alone (e.g., discrete) memory (e.g., a memory that is the primary component within an IC). The memory is preferably a volatile memory, examples of which include static random access memory (SRAM) and dynamic random access memory (DRAM).

FIG. 1 depicts an illustrative six-transistor (6T) SRAM cell 100. As shown in the figure, the 6T cell 100 comprises a storage element 102 connected to first bitline 111 via a first NMOS access transistor 121 and connected to a second bitline 112 via a second NMOS access transistor 136. More particularly, a drain (D) of first access transistor 121 is preferably connected to the first bitline 111 at a first node, N1, and a drain of second access transistor 136 is connected to the second bitline 112 at a second node, N2. A source (S) of transistor 121 is coupled to the storage element 102 at a third node, N3, and a source of transistor 136 is coupled to the storage element at a further node, N4. Gates (G) of access transistors 121 and 136 are coupled to a wordline 113, such that a control signal supplied by the wordline, depending upon a voltage level thereof, is operative to selectively control activation of the access transistors.

The storage element 102 may comprise a pair of inverters connected in a cross-coupled latch configuration and operative to store a data state of the memory cell 100. Specifically, storage element 102 preferably includes a first drive transistor 122, a second drive transistor 123, a third drive transistor 124 and a fourth drive transistor 135; a first inverter includes first and third drive transistors 122 and 124, respectively, and a second inverter includes second and fourth drive transistors 123 and 135, respectively. The first drive transistor 122 is preferably an NMOS pull-down transistor having a source coupled to a first power supply 161, a drain coupled to node N4, and a gate coupled to node N3. The second drive transistor 123 is an NMOS pull-down transistor having a source coupled to the first power supply 161, a drain coupled to node N3, and a gate coupled to node N4. The third drive transistor 124 is a PMOS pull-up transistor having a source coupled to a second power supply 162, a drain coupled to node N4, and a gate coupled to node N3. The fourth drive transistor 135 is a PMOS pull-up transistor having a source coupled to the second power supply 162, a drain coupled to node N3, and a gate coupled to node N4.

The first power supply 161 may be, for example, VSS providing about zero volts, although the invention is not limited to this specific voltage. The second power supply 162 may be, for example, VDD providing about one volt, although the invention is not limited to this specific voltage. One of two logical data states (e.g., logic “0” or logic “1” data states, which may be assigned to voltage levels zero and one volt, respectively) is stored, at any given time, within the 6T memory cell 100 during normal operation (e.g., when VDD and VSS are supplied). Although the logic states can be arbitrarily assigned, a “0” data state is preferably indicative of a voltage on node N3 being less than a voltage on node N4. For example, the voltage on node N3 may be VSS or 0 volt and the voltage on node N4 may be VDD or one volt. A “1” data state is preferably indicative of the voltage on node N3 being greater than the voltage on node N4. For example, the voltage on node N3 may be VDD or 1 volt and the voltage on node N4 may be VSS or zero volt.

The 6T memory cell 100, when powered up, is preferably operative in one of at least three modes: a write mode comprising a write operation, a read mode comprising a read operation, and a store mode. During the store mode, the written data state is stored and the 6T cell 100 is either in a precharge phase or has been precharged, and the precharged voltage levels on the first bitline 111 and the second bitline 112 are being maintained (e.g., hold phase). When employed in a typical memory circuit, the 6T memory cell 100 will be predominantly in the store mode.

During a write operation where a “1” data state is to be written into the 6T memory cell 100, the first bitline 111 is set to VDD, the second bitline 112 is set to VSS, and the wordline 113 is raised to VDD, thereby turning on (i.e., activating) the first and second access transistors 121, 136. Turning on transistor 121 forces node N3 to the voltage level of the first bitline 111, which in this instance is VDD, assisted by pull-up transistor 135. Likewise, node N4 will be pulled down to VSS through either or both of access transistor 136 and pull-down transistor 122. The write operation thus sets the latch storage element 102 to store the “1” data state.

During a write operation where a “0” data-state is to be written into the 6T memory cell 100, the first bitline 111 is set to VSS, the second bitline 112 is set to VDD, and the wordline 113 is raised to VDD, thereby turning on the first and second access transistors 121, 136. Turning on transistor 136 forces node N4 to the voltage level of the second bitline 112, in this case VDD, assisted by pull-up transistor 124. Similarly, node N3 will be pulled down to VSS through either or both of access transistor 121 and pull-down transistor 123. The write operation thus sets the latch storage element 102 to store the “0” data state.

During a precharge phase in a given memory cycle, the wordline 113 is preferably set to VSS so that the first and second access transistors 121 and 136, respectively, are turned off (e.g., inactive or off-state). Typically, both the first bitline 111 and the second bitline 112 are set to approximately the same voltage level during the precharge phase, such as, for example, VDD or one volt. During the precharge phase, the 6T memory cell 100 retains the data state that was previously written into the cell and is ready for a subsequent read operation.

A read operation of the 6T memory cell 100 is preceded by the precharge phase. Prior to the read operation, the first bitline 111 and the second bitline 112 are set to approximately equal voltages, such as, for example VDD or 1 volt, and then released and allowed to float at these voltage levels or, alternatively, are kept at these voltage levels by relatively weak precharge “keeper” transistors (not explicitly shown). In this example, the first bitline 111 and the second bitline 121 are precharged to VDD, although the invention is not limited to any particular precharge voltage level.

When reading a logic “1” data state, wordline 113 is preferably set to VDD, thereby turning on the first and second access transistors 121, 136 so that the first bitline 111 is pulled up towards (or at least not pulled down from) VDD, and the second bitline 112 is pulled down towards VSS. The first bitline 111 may be pulled up towards VDD through the series arrangement of the first access transistor 121 and the fourth drive transistor 135. The second bitline 112 is pulled down towards VSS through the series arrangement of the second access transistor 136 and the first drive transistor 122. A sense amplifier operatively coupled to the first and second bitlines 111 and 112, respectively, senses the voltage differential between the first and second bitlines, and recognizes the read data as a “1” data state. Alternatively, when reading a “0” data state, wordline 113 is set to VDD, thereby turning on the first and second access transistors 121 and 136, respectively, so that the second bitline 112 is pulled up towards (or at least not pulled down from) VDD, and the first bitline 111 is pulled down towards VSS. The second bitline 112 may be pulled up towards VDD through the series arrangement of the second access transistor 136 and the third drive transistor 124. The first bitline 111 is pulled down towards VSS through the series arrangement of the first access transistor 121 and the second drive transistor 123. The sense amplifier senses the voltage differential between the first and second bitlines 111, 112 and recognizes the read data as a “0” data state.

Consider leakage currents flowing through three of the six transistors in the 6T memory cell 100 when the cell is in the store mode storing a “0” data-state (wordline 113 is at VSS), and the first and second bitlines 111, 112 are at VDD. In the “0” data state, node N3 is at VSS and node N4 (being a logical complement of node N3) is at VDD. More particularly, consider a first leakage current 171 flowing through the first access transistor 121, which is turned off. The source of transistor 121 is at VSS (node N3), the drain of transistor 121 is at VDD (first bitline 111), and the gate of transistor 121 is at VSS (wordline 113). Although transistor 121 is biased in the off-state, the relatively large voltage difference between its drain and source (e.g., VDD−VSS) enables the first leakage current 171 to flow from the first bitline 111 through transistor 121 to node N3, and then to the first power supply 161 through transistor 123, which is biased in the “on” state (i.e., turned on).

Consider a second leakage current 172 flowing through the first drive transistor 122. The source of transistor 122 is at VSS (first power supply 161), the drain of transistor 122 is at VDD (node N4), and the gate of transistor 122 is at VSS (node N3). Although transistor 122 is biased in the “off” state (i.e., turned off), the relatively large voltage difference between its drain and source (e.g., VDD−VSS) enables the second leakage current 172 to flow from the second power supply 162 through transistor 124, which is biased in the “on” state, to node N4, and then through transistor 122 to the first power supply 161.

Next, consider a third leakage current 173 flowing through the fourth drive transistor 135. The source of transistor 135 is at VDD (second power supply 162), the drain of transistor 135 is at VSS (node N3), and the gate of transistor 135 is at VDD (node N4). Although transistor 135 is biased in the “off” state, there will be a relatively large voltage difference between the drain and source of transistor 135 (e.g., VSS−VDD) which enables the third leakage current 173 to flow from the second power supply 162 through transistor 135 to node N3, and then to the first power supply 161 through the second drive transistor 123, which is biased in the “on” state.

Therefore, when storing a “0” data state and when the first and second bitlines 111, 112 are at VDD (e.g., as during or after the precharge phase), the 6T memory cell 100 has at least three leakage paths corresponding to the first leakage current 171 through transistor 121, the second leakage current 172 through transistor 122, and the third leakage current 173 through transistor 135. In a similar fashion, when storing a “1” data state, there will also be at least three leakage paths corresponding to leakage currents flowing through the second access transistor 136, the second drive transistor 123, and the third drive transistor 124 (not explicitly shown).

In a given memory circuit, a plurality of 6T memory cells (100) may be employed; for example, a first 6T cell and a second 6T cell coupled to the first and second bitlines 111, 112. When the first 6T cell is being written, either the first bitline 111 or the second bitline 112 will be at or near VSS. For this example, it is assumed that during a write operation on the first 6T cell, the second bitline 112 is at VSS. Also for this example, it is assumed that the second 6T cell is storing a “0” data state with node N3 at VSS and node N4 at VDD. This situation creates a fourth leakage current 174 flowing through the second access transistor 136, with the source of transistor 136 at VSS (second bitline 112), the drain of transistor 136 at VDD (node N4), and the gate of transistor 136 at VSS (wordline 113). The leakage current 174 flows from the second power supply 162, through the third drive transistor 124 to node N4, and then through transistor 136 to the second bitline 112.

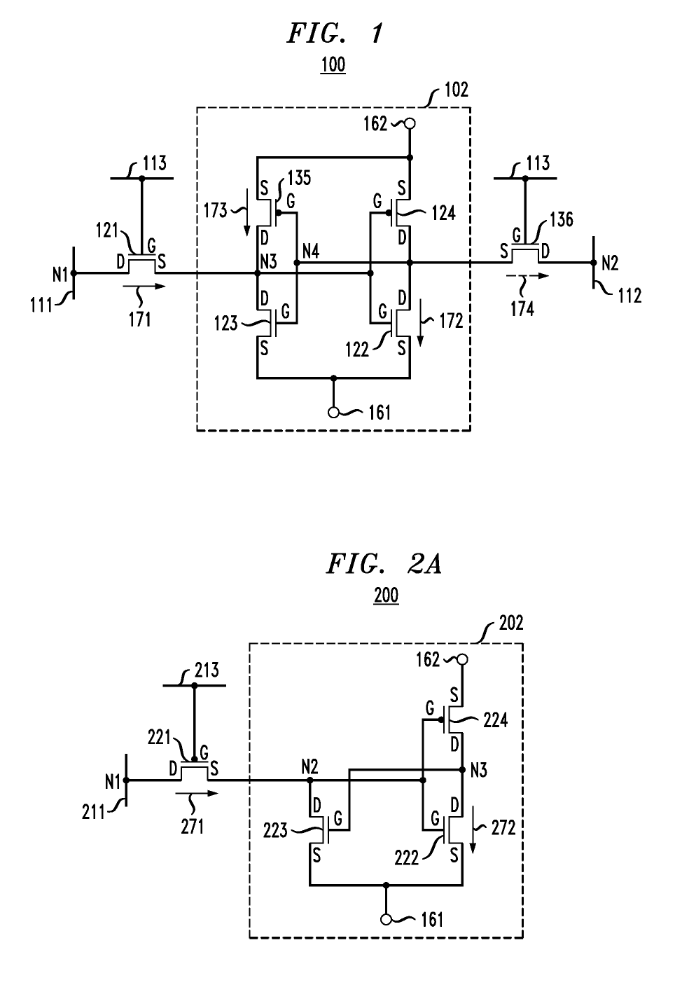

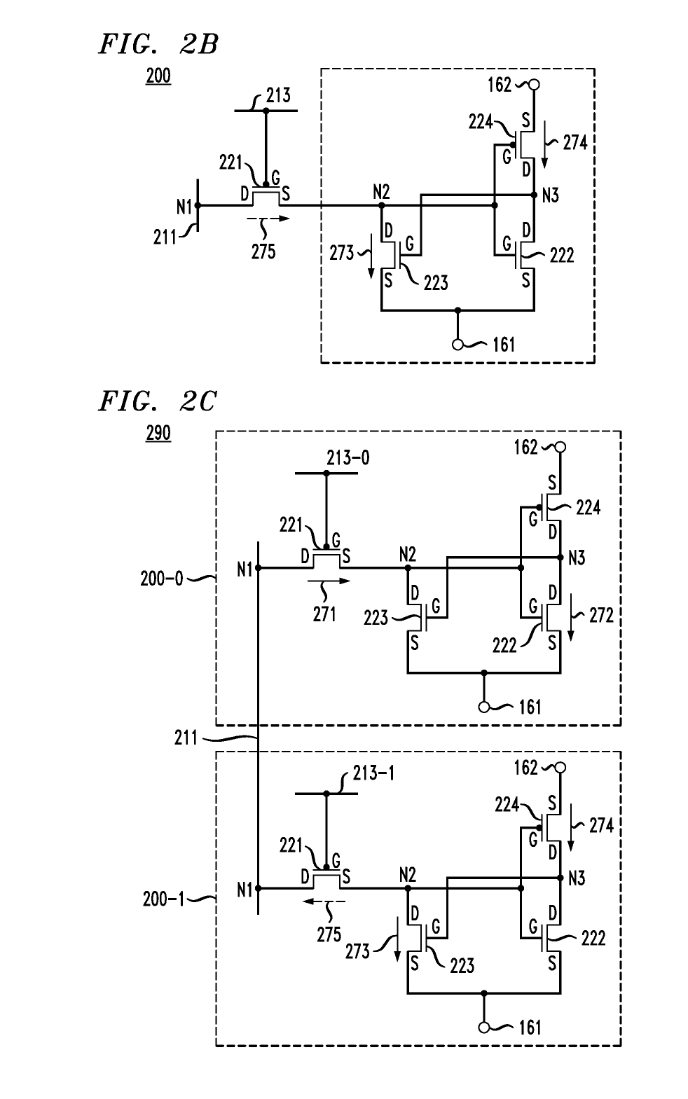

U.S. Patent Application Publication No. 2007/0177419, the disclosure of which is incorporated herein by reference in its entirety for all purposes, discloses, in FIG. 2 thereof, a 4T SRAM cell 200 comprising two access transistors (MP2 and MN2) and two drive transistors (MP1 and MN1). The two drive transistors configured to selectively couple each of first and second storage nodes, A and B, to corresponding low and high voltage power supplies, VL and VH, respectively, and to maintain a first logic state through a feedback loop. The two access transistors are configured to selectively couple each of the first and second storage nodes to corresponding first and second bitlines, BL and ˜BL, and to maintain a second logic state through relative transistor leakage currents. However, within conventional memory cells that utilize leakage current to maintain one stored data state on both internal storage nodes, the data state maintained by leakage current is only weakly maintained and is therefore highly susceptible to data disturbs attributable to noise, process, voltage and/or temperature (PVT) variations, and/or other mechanisms. Such a conventional memory cell arrangement undesirably impacts manufacturing yield and/or device reliability.

Aspects of the invention beneficially provide an improved memory cell that includes fewer transistors than the illustrative 6T memory cell 100 shown in FIG. 1, and therefore may be advantageously formed within a smaller area than the 6T cell. An IC comprising memory including a plurality of memory cells according to embodiments of the invention occupies less area and may therefore be fabricated at a reduced cost compared to memory comprised of 6T memory cells (e.g., memory cell 100 shown in FIG. 1). Furthermore, aspects of the invention provide a memory cell having fewer leakage current paths and less overall leakage current compared to conventional SRAM cells. An IC comprising memory including a plurality of memory cells according to embodiments of the invention thus consumes less leakage current and exhibits reduced total power consumption than an SRAM comprising 6T memory cells.

Aspects of the present invention provide a memory cell which is significantly less susceptible to certain conditions such as data disturbs attributable to noise, PVT variations, and/or other mechanisms, compared to conventional memory cells, and therefore exhibits superior manufacturing yield and device reliability. As will be described in further detail below, a memory cell according to embodiments of the invention overcome these and other weaknesses exhibited by standard memory cells, in at least one aspect, by maintaining both data states in the memory cell using active current on at least one of two internal storage nodes in the cell.

With reference now to FIGS. 2A and 2B, at least a portion of an exemplary SRAM cell 200 is shown, according to an embodiment of the invention. FIG. 2A depicts the exemplary memory cell 200 illustrating corresponding leakage currents flowing through selected transistors in the cell when storing a logic “0” data state, and FIG. 2B depicts the exemplary memory cell 200 and corresponding leakage currents flowing through selected transistors in the cell when storing a logic “1” data state.

The memory cell 200 comprises four transistors and is hence referred to herein as a 4T SRAM cell. Specifically, memory cell 200 includes a first PMOS transistor 221 or alternative switching element (e.g., pass gate), which may be considered an access device, having a drain coupled to a bitline 221 at a first node N1, a gate coupled to a wordline 213 for receiving a control signal operative to selectively activate the access device, and a source coupled to a storage element 202 at a second node N2. The storage element 202 preferably comprises a first NMOS pull-down transistor 222, a second NMOS pull-down transistor 223 and a PMOS pull-up transistor 224. Transistor 222 is arranged having a source coupled to a first voltage supply 161, which may be VSS (e.g., about zero volts), a drain connected to a third node N3, and a gate connected to node N2. Transistor 223 is arranged having a source coupled to the first voltage supply 161, a drain connected to node N2, and a gate connected to node N3. Transistor 224 is arranged having a source coupled to a second voltage supply 162, which may be VDD (e.g., about one volt), a drain connected to node N3, and a gate connected to node N2. Transistors 222 and 224 are configured to form an inverter.

It is to be appreciated that, because a metal-oxide-semiconductor (MOS) device is symmetrical in nature, and thus bidirectional, the assignment of source and drain designations in the MOS device is essentially arbitrary. Therefore, the source and drain may be referred to herein generally as first and second source/drain, respectively, where “source/drain” in this context denotes a source or a drain.

In a memory array application, a plurality of memory cells 200 are preferably arranged into a plurality of rows and columns, with each memory cell residing at an intersection of a unique row and column pair. To write or read a given memory cell within the memory array, a selected row is activated, thereby activating memory cells coupled to the selected row and enabling at least one of the cells of the selected row to be written to or read from via at least one corresponding bitline coupled to the given cell of the selected row.

Operation of memory cell 200 will now be described. The first voltage supply 161 is preferably VSS providing, for example, zero volt. The second voltage supply 162 is preferably VDD providing, for example, one volt. One of two data-states (e.g., “0” or “1” data-states) is stored, at any given time, within memory cell 200 during normal operation. Although arbitrarily assigned, a “0” data state corresponds to the voltage on node N2 being less than the voltage on node N3. For example, a “0” data state may be indicative of the voltage on node N2 being VSS or zero volt and the voltage on node N3 being VDD or one volt. Alternatively, a “1” data state corresponds to the voltage on node N2 being greater than the voltage on node N3. For example, a “1” data state may be indicative of the voltage on node N2 being VDD or 1 volt and the voltage on node N3 being VSS or zero volt.

Memory cell 200, when powered on, may be in one of at least three modes: a write mode comprising a write operation, a read mode comprising a read operation, and a store mode. During the store mode, the written data state is stored and memory cell 200 is either in a precharge phase or a hold phase (following the precharge phase). In the precharge phase, the bitline 211 is set to a prescribed voltage level, which may be a precharge voltage level, such as, for example, VDD or one volt. In the hold phase, the precharge voltage level on the bitline 211 is maintained.

During a write operation where a “1” data state is written into memory cell 200, the bitline 211 is set to VDD and the wordline 213 is lowered to VSS, thereby activating (i.e., turning on or placing in an on-state) PMOS access transistor 221. Transistor 221, being turned on, forces node N2 to VDD. Node N2 being at a high level (VDD) turns off PMOS transistor 224 and turns on NMOS transistor 222, thereby pulling down node N3 to VSS and holding NMOS transistor 223 in an off state. In this manner, a “1” data state is written into memory cell 200.

It should be appreciated that, although shown as a PMOS transistor 221, the access device in memory cell 200 may alternatively comprise an NMOS transistor device or a combination of PMOS and NMOS devices (e.g., complementary pass-gate). As is known in the art, PMOS transistors are conductive when a logic low level voltage, which may be VSS (e.g., 0 volt), is applied to their gates. Thus, in order to activate PMOS device 221, and thereby access (e.g., read or write) memory cell 200, a voltage difference between the wordline 213 and bitline 211 at least equal to a transistor threshold voltage, Vₜ, of the device is applied. When the wordline 213 is at a logic high level (e.g., VDD or 1.0 volt), PMOS transistor 221 is non-conductive. Alternatively, NMOS transistors are conductive when a logic high level voltage, which may be VDD (e.g., about 1.0 volt), is applied to their gates. When using an NMOS access device, other bias voltages would be modified accordingly, as will become apparent to those skilled in the art.

During a write operation where a “0” data state is written into memory cell 200, the bitline 211 is set to VSS and the wordline 213 is lowered to VSS, thereby turning on (on-state) access transistor 221. Transistor 221, being biased in an active (on) state, forces node N2 equal to about VSS plus a magnitude of a MOS transistor threshold voltage (i.e., V_{N2}=VSS+Vₜ, where Vₜ is a magnitude of the threshold voltage of transistor 221). Node N2 being at a low level (VSS) turns off NMOS transistor 222 and turns on PMOS transistor 224, thereby pulling up node N3 to VDD and holding NMOS transistor 223 in an on state. Node N3 is consequently set to VDD through transistor 224 and node N2 is reduced further to substantially VSS by transistor 223. In this manner, a “0” data state is written into memory cell 200.

During a precharge phase of memory cell 200, the wordline 213 is set to VDD so that access transistor 221 is disabled (i.e., in an off state). Bitline 211 is preferably set to a precharge voltage level, for example, VDD or one volt. In some embodiments, the precharge voltage level may be greater than VDD, which may require a separate precharge voltage source. During the precharge phase, memory cell 200 retains the data state that was previously written into the cell. After the precharge phase, the memory cell 200 is ready for a read operation.

A read operation of memory cell 200 is preceded by the precharge phase. Prior to the read operation of memory cell 200, the bitline 211 is set to the precharge voltage level, for example VDD or 1 volt, and is then released to float at this voltage level or, alternately, is kept at this voltage level by a relatively weak precharge keeper transistor (not explicitly shown). In this example, the bitline 211 is precharged to VDD, although the invention is not limited to any particular precharge voltage level.

During a read operation of a “1” data state, the wordline 213 is set to VSS, thereby turning on transistor 221 so that the bitline 211 is pulled up towards, or is maintained at, VDD. Because node N2 is at VDD (since a “1” data state is being stored in the cell prior to the read operation), the bitline 211 will not be pulled down towards VSS when transistor 221 is turned on. Consequently, the precharge voltage level is maintained on the bitline 211. A sense amplifier coupled to the bitline 211 is adapted to measure the voltage on the bitline and recognizes the read data as a “1” data state.

Likewise, during a read operation of a “0” data state, the wordline 213 is set to VSS, thereby turning on access transistor 221. Because node N2 is at VSS (since a “0” data state is being stored in the cell prior to the read operation), the bitline 211 will discharge towards VSS through the series arrangement of transistor 221 and transistor 223. The sense amplifier coupled to the bitline 211 measures the voltage on the bitline and recognizes the read data as a “0” data state.

After data has been written into memory cell 200, the cell maintains the data, for example, while in the hold phase or while cells on other rows of an array are being accessed (e.g., written or read). Retaining a “1” data state in the memory cell 200 corresponds to, for example, maintaining VDD on node N2 and maintaining VSS on node N3. Alternatively, retaining a “0” data state in the cell 200 corresponds to, for example, maintaining VSS on node N2 and maintaining VDD on node N3.

According to an aspect of the invention, during a store mode, a “1” data state is maintained in memory cell 200 by retaining a high voltage level (e.g., VDD) on node N2 via leakage current through PMOS transistor 221, which is biased in the off state, and by retaining a low voltage level (e.g., VSS) on node N3 via active current through NMOS transistor 222, which is biased in the on state. Alternatively, a “0” data state is maintained in memory cell 200 by retaining a low voltage level on node N2 via active current through NMOS transistor 223, which is biased in the on state, and by retaining a high voltage level on node N3 via active current through transistor 224, which is also biased in the on state.

Leakage current associated with the access transistor 221 is, for example, sub-threshold leakage current that flows between the source and drain of the transistor when the gate is biased so that transistor 221 is in the off state. The source of transistor 221 comprises a source diode junction between the source and the substrate or tub of transistor 221; the drain of transistor 221 comprises a drain diode junction between the drain and the substrate or tub of transistor 221. Alternative or additional leakage components may include, for example, leakage currents through the source diode junction and/or the drain diode junction of transistor 221.

With continued reference to FIG. 2A, consider leakage currents flowing through certain transistors in memory cell 200 when the cell is in the store mode, storing a “0” data state, and the bitline 211 is at VDD. In the “0” data state, node N2 will be at VSS and node N3, being a logical complement of node N2, will be at VDD. Consider a first leakage current 271 flowing through access transistor 221. The source of transistor 221 (node N2) is at VSS, the drain (bitline 211) of transistor 221 is at VDD, and the gate (wordline 213) of transistor 221 is at VSS. Although transistor 221 is biased in the off state, the relatively large voltage difference between the drain and source (e.g., VDD−VSS) enables the first leakage current 271 to flow from the bitline 211, through transistor 221 to node N2, and then to the first power supply 161 through transistor 223 which is biased in the on state.

Consider a second transistor leakage current 272 flowing through the NMOS pull-down transistor 222. The source of transistor 222 is at VSS (first power supply 161), the drain of transistor 222 is at VDD (node N3), and the gate of transistor 222 is at VSS (node N2). Like transistor 221, although transistor 222 is biased in the off state, the relatively large voltage difference between the drain and source of transistor 222 (e.g., VDD−VSS) enables the second leakage current 272 to flow from the second power supply 162, through PMOS transistor 224, which is biased in the on state, to node N3, and then through transistor 222 to the first voltage supply 161.

Therefore, memory cell 200 has essentially only two leakage paths corresponding to the first leakage current 271 and the second leakage current 272 when storing a “0” data state and when the bitline 211 is at VDD, as during or after the precharge phase. Note, that illustrative memory cell 200 has fewer leakage paths than memory cell 100 shown in FIG. 1, and hence memory cell 200 beneficially achieves reduced overall current consumption compared to memory cell 100.

With reference now to FIG. 2B, consider leakage currents flowing through certain transistors in memory cell 200 when the cell is in the store mode, storing a “1” data state, and the bitline 211 is at VDD. In the “1” data state, node N2 will be at VDD and node N3 will be at VSS. In this exemplary embodiment, like in the embodiment shown in FIG. 2A, there are also two leakage paths. Specifically, consider a third leakage current 273 flowing through NMOS transistor 223. The source of transistor 223 (first voltage supply 161) is at VSS, the drain of transistor 223 (node N2) is at VDD, and the gate of transistor 221 (node N3) is at VSS. Although transistor 223 is biased in the off state, the relatively large voltage difference between the drain and source (e.g., VDD−VSS) of transistor 223 enables the third leakage current 273 to flow from node N2, through transistor 223, to the first voltage supply 161.

Additionally, consider a fourth leakage current 274 flowing through PMOS transistor 224. The source of transistor 224 (second voltage supply 162) is at VDD, the drain of transistor 224 (node N3) is at VSS, and the gate of transistor 224 (node N2) is at VDD. Although transistor 224 is biased in the off state, the relatively large voltage difference between the source and drain (e.g., VDD−VSS) of transistor 224 enables the fourth leakage current 274 to flow from the second voltage supply 162, through transistor 224, to node N3, and then to the first power supply 161 through transistor 222, which is biased in the on state.

In a memory circuit application, there is typically a plurality of memory cells coupled to a given bitline. FIG. 2C illustrates at least a portion of an exemplary memory circuit 290 comprising a plurality of memory cells coupled to a given bitline, according to an embodiment of the invention. Although only two memory cells are shown for economy of description, the present invention is not limited to any particular number of memory cells in the memory circuit, as will become apparent to those skilled in the art given the teachings herein. One or both of the memory cells may be formed in a manner consistent with exemplary memory cell 200 shown in FIGS. 2A and 2B.

By way of example only and without loss of generality, in memory circuit 290 it is assumed that a first memory cell, 200-0, in the memory circuit 290 is being written (e.g., write mode) to store a “0” data state and a second memory cell, 200-1, is storing a “1” data state (e.g., store mode). Both the first and second memory cells 200-0 and 200-1 are coupled to the same bitline. Specifically, node N1 in each of the memory cells 200-0 and 200-1 are connected to bitline 211. As previously described, when storing a “1” data state, node N2 in memory cell 200-1 will be at or near VDD and node N3 will be at or near VSS. Likewise, when writing a “0” data state to memory cell 200-0, node N2 in cell 200-0 is written to VSS.

When memory cell 200-0 is written to a “0” data state, the corresponding bitline 211 coupled to cell 200-0 will be at or near VSS. Since memory cell 200-1 is also coupled to bitline 211, a disturb leakage current 275 will flow through PMOS access transistor 221 in cell 200-1, which is biased in the off state. More particularly, a drain of access transistor 221 (bitline 211) in cell 200-1 will be at VSS, a source of transistor 221 (node N2) will be at VDD (storing a “1” data state), and a gate of transistor 221 (wordline 213-1) will be at VDD.

The disturb leakage current 275 in memory cell 200-1 may undesirably discharge node N2 of cell 200-1 to such a large enough extent that the voltage level on node N2 of cell 200-1 falls below a prescribed threshold which is indicative of a “1” data state when the cell is subsequently read. The lowering of the voltage on node N2 of memory cell 200-1 could turn on transistor 224 of cell 200-1, thereby raising the voltage on node N3 and further lowering the voltage on node N2 of memory cell 200-1 such that the cell 200-1 erroneously stores a “0” data state and has thus been “disturbed.” A similar situation can occur during a read mode. For example, reading a “0” data state from one memory cell may upset or disturb a “1” data state stored in another memory cell, a cell not being read (e.g., deselected memory cell), coupled to the same bitline due to leakage through the access transistor 221 of the deselected cell.

For this reason, the disturb leakage current 275 in each of the memory cells in memory circuit 290 should be minimized through design and/or fabrication of the memory cells. The disturb leakage current 275 may be minimized, for example, by providing access transistor 221 in each of the memory cells 200-0, 200-1 with a relatively long channel length, a relatively high threshold voltage, and/or by including other implants, dimensional features, etc. that operatively reduces leakage current in the cells.

The desire to reduce leakage current through the access transistor of memory cell 200-1 while writing memory cell 200-0—or, more generally, reducing disturb leakage current through the access transistor of a deselected (i.e., unselected) memory cell while another memory cell coupled to the same bitline is being read—appears, at least at first, to be at odds with the objective of providing sufficient leakage current through the access transistor (e.g., transistor 221) to maintain the voltage on node N2 of a given memory cell at a relatively high level (e.g., VDD or one volt) to properly correspond to a “1” data state. However, a workable compromise may be found, for example, by recognizing that the amount of time that the bitline 211 is low during a write or read of the cell is relatively short (e.g., from less than about 1 nanosecond to about 10 nanoseconds) in comparison to the time constant associated with node N2 (e.g., greater than about 100 nanoseconds), thus assisting to prevent substantial leakage of charge off node N2 of the memory cell (e.g., cell 200-0, 200-1).

The objectives of reducing leakage current through the access transistor of the memory cell, reducing leakage current in a deselected memory cell (e.g., a cell not being read), and providing sufficient leakage current through the access transistor so as to maintain the voltage on node N2 at a relatively high level (e.g. VDD or one volt) indicative of a “1” data state, are beneficially achieved, according to an embodiment of the invention, by controlling a back-gate bias voltage on the access transistor 221 of the deselected memory cell(s) in the memory circuit. In this embodiment, the PMOS access transistor 221 is preferably formed within an N-type conductivity tub or well (N-tub). Connection to the N-tub provides a back-gate, coupled to a third voltage supply for supplying back-gate bias, which may comprise a programmable voltage source (not explicitly shown), for applying the back-gate bias to transistor 221.

When a PMOS device is utilized for access transistor 221, a relatively high back-gate bias voltage (e.g., above VDD) reduces leakage current through the access transistor 221, and a relatively low back-gate bias voltage (e.g., at or below VDD) increases leakage current through transistor 221. The opposite holds true when an NMOS access device is used. When writing memory cell 200-0, the back-gate bias voltage is preferably increased on transistor 221 of memory cell 200-1, thereby reducing leakage current through transistor 221 in cell 200-1. For example, in an illustrative embodiment, the back-gate bias voltage of transistor 221 may be increased to 0.4 volt above VDD, although the invention is not limited to any specific level of back-gate bias voltage. During the store mode, the back-gate bias voltage on access transistor 221 of memory cell 200-1 is preferably reduced, thereby increasing the leakage current through transistor 221. For example, the back-gate bias may be decreased to VDD, or some voltage below VDD.

For memory arrays comprising memory cells formed in accordance with aspects of the invention described herein (e.g., memory cell 200 shown in FIGS. 2A and 2B), the N-tubs of all access transistors in all cells within the memory array may be connected in common (e.g., to the same bias source). In this manner, the back-gate bias voltage levels for all of the memory cells can be selectively controlled to correspond to the specific mode(s) of operation of the memory cells (e.g., a relatively high back-gate bias voltage during write or read mode, and a relatively low back-gate bias voltage during store mode).

Alternately, according to other embodiments, it may be advantageous to have N-tubs of the memory cells separated on a row-by-row basis, or some other arrangement; that is, the memory circuit may be formed such that N-tubs of one or more memory cells in one row of the memory circuit are separate from N-tubs of corresponding memory cells in another row of the memory circuit. This arrangement of the memory circuit would allow the back-gate bias corresponding to a selected row including memory cells being accessed (e.g., written or read) to be independently set to a relatively low voltage (e.g., VDD or below) while allowing the back-gate bias on all other unselected rows to be set to a relatively high voltage (e.g., 0.4 volt above VDD). As stated above, the relatively low back-gate bias level enhances memory cell writeability and readability by lowering the threshold voltage of the access transistor (e.g., transistor 221) of the memory cell being written or read.

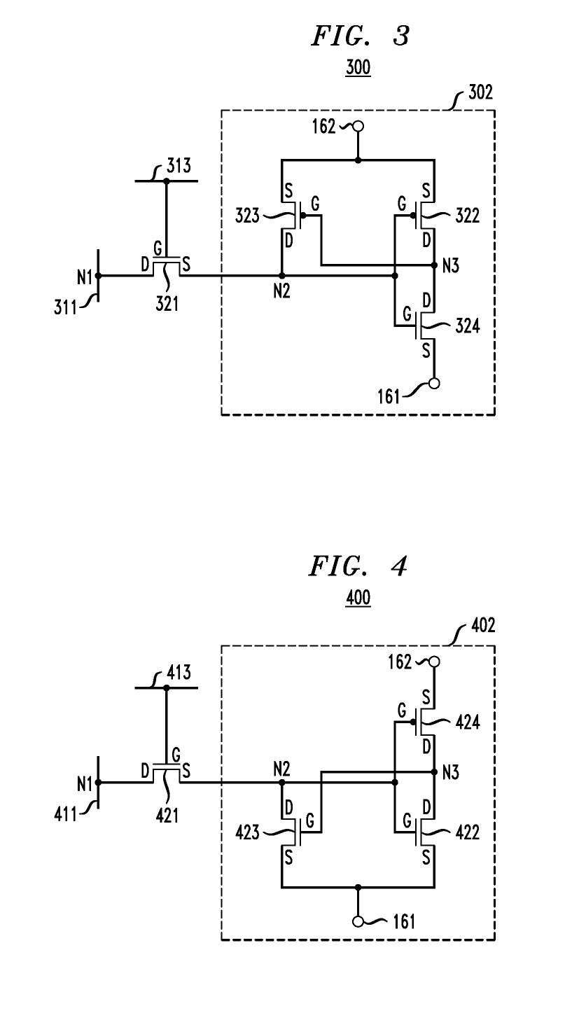

FIG. 3 is a schematic diagram depicting at least a portion of an exemplary 4T SRAM cell 300, according to an embodiment of the invention. Memory cell 300, like memory cell 200 shown in FIG. 2A, includes an access transistor 321, or alternative switching element (e.g., pass gate), having a drain coupled to a bitline 311 at a first node N1, a gate coupled to a wordline 313 for receiving a control signal operative to selectively activate the access transistor, and a source coupled to a storage element 302 at a second node N2. In this alternative embodiment, an NMOS access transistor 321 is used in place of the PMOS access transistor 221 employed in memory cell 200. Consequently, rather than being selected by applying a low logic signal on wordline 213 of memory cell 200 (see FIG. 2A), memory cell 300 is accessed by supplying a high logic signal on the corresponding wordline 313.

The storage element 302 in memory cell 300 is also distinguishable from the storage element 202 in memory cell 200. Specifically, storage element 302 preferably comprises a first PMOS pull-up transistor 322, a second PMOS pull-up transistor 323, and an NMOS pull-down transistor 324. Transistors 322 and 324 are configured as an inverter. Transistor 324 includes a source coupled to a first voltage supply 161, which may be VSS (e.g., ground or zero volts), a drain connected to a drain of transistor 322 at a third node N3, and a gate connected to node N2. Transistor 322 includes a source coupled to a second voltage supply 162, which may be VDD (e.g., 1.0 volt), and a gate connected to node N2. Transistor 323 includes a source coupled to the second voltage supply 162, a drain connected to node N2, and a gate connected to node N3.

During normal operation of memory cell 300, the bitline 311 is precharged, for example, to about the first voltage supply 161, preferably VSS. When memory cell 300 stores a “0” data state, leakage current advantageously assists in maintaining the voltage on node N2 at or near VSS, according to aspects of the invention. More particularly, in memory cell 300, a “0” data state is retained by maintaining node N2 at or near VSS by leakage current flowing through the access transistor 321, and by maintaining node N3 at or near VDD by active current flowing through PMOS pull-up transistor 322, which is biased in the on state. Likewise, in memory cell 300, a “1” data state is retained by maintaining node N2 at or near VDD by active current flowing through PMOS pull-up transistor 323, which is biased in the on state, and by maintaining node N3 at or near VSS by active current through NMOS pull-down transistor 324, which is also biased in the on state.

After data has been written into memory cell 300, the cell maintains the data, for example, while in a hold phase or while memory cells in other rows of a memory array in which memory cell 300 is employed are being accessed (e.g., written to or read from). As previously stated, although arbitrarily assigned, a “0” data state preferably corresponds to the voltage on node N2 being less than the voltage on node N3. For example, a “0” data state may be indicative of the voltage on node N2 being VSS or zero volt and the voltage on node N3 being VDD or one volt. Alternatively, a “1” data state corresponds to the voltage on node N2 being greater than the voltage on node N3. For example, a “1” data state may be indicative of the voltage on node N2 being about VDD or 1 volt and the voltage on node N3 being about VSS or zero volt. It is to be understood that the invention is not limited to any specific voltage levels for defining the respective data states.

Operation of memory cell 300 and leakage currents through certain transistors in cell 300 will be similar to the operation of and leakage currents in memory cell 200 shown in FIGS. 2A and 2B when modified due to symmetrical features between memory cells 300 and 200 as well as the types of transistors (e.g., NMOS or PMOS) used in the respective cells. In particular, in contrast to the operation of memory cell 200 wherein bitline 211 is precharged to a high voltage level, such as VDD (FIG. 2A), bitline 311 is precharged to a low voltage level (e.g., VSS or 0 volt). In some embodiments, the precharge voltage may be below VSS. The operation of and leakage currents in memory cell 300 will become apparent to one skilled in the art given the teachings herein in connection with memory cell 200.

The objectives of reducing leakage current through the access transistor (e.g., transistor 321) of one or more deselected (i.e., unselected) memory cells (e.g., 300) while concurrently accessing (e.g., writing or reading) a selected memory cell coupled to the same bitline (e.g., 311) as the deselected cell(s), and of providing sufficient leakage current through the access transistor of the one or more deselected memory cells to maintain the voltage on node N2 of the cell(s) at a relatively low level (e.g., VSS or 0 volt) indicative of a “0” data state, may be advantageously facilitated, according to an embodiment of the invention, by controlling a back-gate bias voltage on the access transistor 321 of the deselected memory cell(s) in a memory circuit in which the memory cell(s) reside.

In this embodiment, for each memory cell, the NMOS access transistor 321 is formed within a well or tub of P-type conductivity (i.e., a P-tub). Connection to the P-tub to a third voltage supply provides a back-gate bias to the access transistor 321. A relatively low back-gate bias voltage, such as, for example, below VSS, beneficially reduces leakage current through transistor 321, and a relatively high back-gate bias voltage, such as, for example, at or above VSS, increases leakage current through transistor 321. When accessing a given memory cell (e.g., writing or reading the cell) in a memory circuit, the back-gate bias voltage is preferably decreased on the access transistor (e.g., transistor 321) of a deselected memory cell (e.g., cell 300), thereby reducing leakage current through transistor 321. For example, in an illustrative embodiment, the back-gate bias voltage of transistor 321 may be decreased to about 0.4 volt below VSS, although the invention is not limited to any specific level of back-gate bias voltage. During the store mode, the back-gate bias voltage on access transistor 321 of the deselected memory cell 300 is preferably increased, thereby increasing the leakage current through transistor 321. For example, the back-gate bias may be increased to VSS, or some voltage above VSS (e.g., up to about 0.5 volt above VSS).

For memory arrays comprising memory cells formed in accordance with aspects of the invention described herein (e.g., memory cell 300 shown in FIG. 3), the P-tubs of all access transistors in all cells within the memory array may be connected in common (e.g., to the same bias source). In this manner, the back-gate bias voltage levels for all of the memory cells in the array can be selectively controlled to correspond to the specific mode(s) of operation of the memory cells (e.g., a relatively low back-gate bias voltage during write or read mode, and a relatively high back-gate bias voltage during store mode).

Alternately, according to other embodiments, it may be advantageous to have P-tubs of the memory cells separated on a row-by-row basis, or some other arrangement; that is, the memory circuit may be formed such that P-tubs of one or more memory cells in one row of the memory circuit are separate from P-tubs of corresponding memory cells in another row of the memory circuit. This arrangement of the memory circuit would allow the back-gate bias corresponding to a selected row including memory cells being accessed (e.g., written or read) to be independently set to a relatively high voltage (e.g., VSS or above) while allowing the back-gate bias on all other deselected rows to be set to a relatively low voltage (e.g., 0.4 volt below VSS). As stated above, the relatively high back-gate bias level enhances memory cell writeability and readability by lowering the threshold voltage of the access transistor (e.g., transistor 321) of the memory cell being written or read.

FIG. 4 is a schematic diagram depicting at least a portion of an exemplary 4T SRAM cell 400, according to yet another embodiment of the present invention. Like the illustrative memory cell 300 shown in FIG. 3, memory cell 400 comprises an NMOS access transistor 421 including a drain coupled to a bitline 411 at a first node N1, a gate coupled to a wordline 413 for receiving a control signal operative to selectively activate the access transistor, and a source coupled to a storage element 402 at a second node N2. Storage element 402 may be formed in a manner consistent with storage element 202 shown in FIGS. 2A and 2B. Consequently, operation of memory cell 400 and leakage currents through certain transistors in cell 400 will be substantially the same as the operation of and leakage currents in memory cell 200 shown in FIGS. 2A and 2B and described above.

Specifically, storage element 402 preferably comprises a first NMOS pull-down transistor 422, a second NMOS pull-down transistor 423 and a PMOS pull-up transistor 424. Transistor 422 is arranged having a source coupled to a first voltage supply 161, which may be VSS (e.g., about zero volts), a drain connected to a third node N3, and a gate connected to node N2. Transistor 423 is arranged having a source coupled to the first voltage supply 161, a drain connected to node N2, and a gate connected to node N3. Transistor 424 is arranged having a source coupled to a second voltage supply 162, which may be VDD (e.g., about one volt), a drain connected to node N3, and a gate connected to node N2. Transistors 422 and 424 are configured to form an inverter.

During normal operation of memory cell 400, the bitline 411 is precharged to a prescribed voltage, such as, for example, VDD (e.g., about 1.0 volt), when the second voltage supply 162 is at VDD. As described above in conjunction with memory cell 200 shown in FIGS. 2A and 2B, when memory cell 400 is storing a “1” data state, leakage current beneficially assists in maintaining the voltage on node N2 at or near VDD, according to aspects of the invention. More particularly, in memory cell 400, a “1” data state is retained by maintaining node N2 at or near VDD by leakage current flowing through the access transistor 421, and by maintaining node N3 at or near VSS by active current flowing through transistor 422, which is biased in the on state. Likewise, in memory cell 400, a “0” data state is retained in cell 400 by maintaining node N2 at or near VSS by active current flowing through NMOS pull-down transistor 423, which is biased in the on state, and by maintaining node N3 at or near VDD by active current flowing through PMOS pull-up transistor 424, which is also biased in the on state.

After data has been written into memory cell 400, the cell maintains the data, for example, while in a hold phase or while memory cells in other rows of a memory array in which memory cell 400 is employed are being accessed (e.g., written to or read from). As previously stated, although arbitrarily assigned, a “0” data state preferably corresponds to the voltage on node N2 being less than the voltage on node N3. For example, a “0” data state may be indicative of the voltage on node N2 being VSS or zero volt and the voltage on node N3 being VDD or one volt. Alternatively, a “1” data state corresponds to the voltage on node N2 being greater than the voltage on node N3. For example, a “1” data state may be indicative of the voltage on node N2 being about VDD or 1 volt and the voltage on node N3 being about VSS or zero volt. It is to be understood that the invention is not limited to any specific voltage levels for defining the respective data states.

Operation of memory cell 400 and leakage currents through certain transistors in cell 400 will be substantially the same as in memory cell 200 shown in FIG. 2A and described above, when modified due to the use of an NMOS access transistor in contrast to the PMOS access transistor used in memory cell 200. Storage element 402 in memory cell 400 is essentially the same as storage element 202 in memory cell 200 (FIG. 2A), and therefore operation of the storage element will be substantially the same as storage element 202 described above. The operation of and leakage currents in memory cell 400 will therefore become apparent to those skilled in the art given the teachings herein.

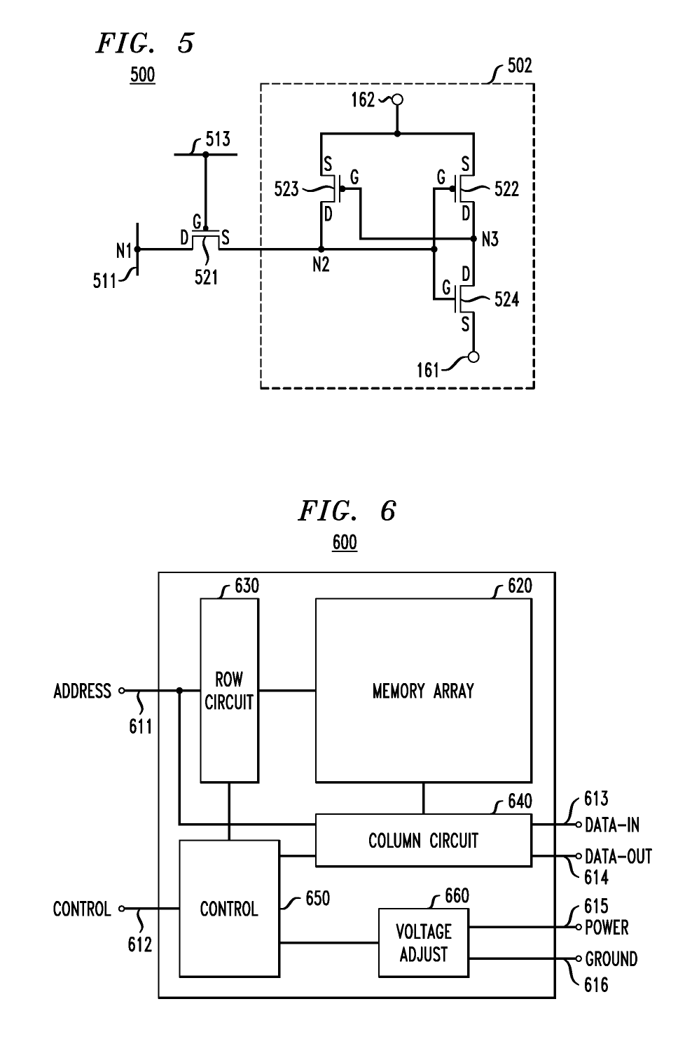

FIG. 5 is a schematic diagram depicting at least a portion of an exemplary four-transistor SRAM cell 500, according to a fourth embodiment of the present invention. Like memory cell 200 depicted in FIG. 2A, memory cell 500 comprises a PMOS access transistor 521 including a drain coupled to a bitline 511 at a first node N1, a gate coupled to a wordline 513 for receiving a control signal operative to selectively activate the access transistor, and a source coupled to a storage element 502 at a second node N2. Storage element 502 includes a first PMOS pull-up transistor 522, a second pull-up transistor 523, and an NMOS pull-down transistor 524. Transistor 524 includes a source coupled to a first voltage supply 161, which may be VSS (e.g., ground or zero volts), a drain connected to a drain of transistor 522 at a third node N3, and a gate connected to node N2. Transistor 522 includes a source coupled to a second voltage supply 162, which may be VDD (e.g., about 1.0 volt), and a gate connected to node N2. Transistor 523 includes a source coupled to the second voltage supply 162, a drain connected to node N2, and a gate connected to node N3.

Storage element 502 in this embodiment is essentially the same as storage element 302 depicted in FIG. 3, and therefore storage element 502 will be operative in a manner consistent with storage element 302 described above. Alternative storage element configurations are similarly contemplated by, and in within the scope of, the present invention.

More particularly, during normal operation of memory cell 500, the bitline 511 is precharged, for example, to about the first voltage supply 161, preferably VSS (e.g., zero volts). When memory cell 500 stores a “0” data state, leakage current advantageously assists in maintaining the voltage on node N2 at or near VSS, according to aspects of the invention. Specifically, in memory cell 500, a “0” data state is retained by maintaining node N2 at or near VSS by leakage current flowing through the access transistor 521, and by maintaining node N3 at or near VDD by active current flowing through PMOS pull-up transistor 522, which is biased in the on state. Likewise, in memory cell 500, a “1” data state is retained by maintaining node N2 at or near VDD by active current flowing through PMOS pull-up transistor 523, which is biased in the on state, and by maintaining node N3 at or near VSS by active current through NMOS pull-down transistor 524, which is also biased in the on state.

After data has been written into memory cell 500, the cell maintains the data, for example, while in a hold phase or while memory cells in other rows of a memory array in which memory cell 500 is employed are being accessed (e.g., written to or read from). Although arbitrarily assigned, a “0” data state may be indicative of the voltage on node N2 being less than the voltage on node N3. For example, a “0” data state may correspond to the voltage on node N2 being VSS or zero volt and the voltage on node N3 being VDD or one volt. Alternatively, a “1” data state may be indicative of the voltage on node N2 being greater than the voltage on node N3. For example, a “1” data state may correspond to the voltage on node N2 being about VDD or 1 volt and the voltage on node N3 being about VSS or zero volt. It is to be understood that the invention is not limited to any specific voltage levels for defining the respective data states.

Operation of memory cell 500 and leakage currents through certain transistors in cell 500 will be similar to the operation of and leakage currents in memory cell 300 shown in FIG. 3 when modified due to symmetrical features between memory cells 500 and 300 as well as the types of transistors (e.g., NMOS or PMOS) used in the respective cells. For example, in contrast to the operation of memory cell 300 wherein NMOS access transistor 321 is activated by application of a logic high signal (e.g., one volt) on the corresponding wordline 313 (FIG. 3), PMOS access transistor 521 in memory cell 500 is activated by application of a logic low signal (e.g., zero volt) on the corresponding wordline 513. In some embodiments, the precharge voltage may be below VSS. The operation of and leakage currents in memory cell 500 will become apparent to one skilled in the art given the teachings herein in connection with memory cell 300.

The objectives of reducing leakage current through the access transistor (e.g., transistor 521) of one or more deselected (i.e., unselected) memory cells (e.g., 500) while concurrently accessing (e.g., writing or reading) a selected memory cell coupled to the same bitline (e.g., 511) as the deselected cell(s), and of providing sufficient leakage current through the access transistor of the one or more deselected memory cells to maintain the voltage on node N2 of the cell(s) at a relatively low level (e.g., VSS or 0 volt) indicative of a “0” data state, may be advantageously facilitated, according to an embodiment of the invention, by controlling a back-gate bias voltage on the access transistor 521 of the deselected memory cell(s) in a memory circuit in which the memory cell(s) reside.

FIG. 6 is a block diagram depicting at least a portion of an exemplary memory circuit 600, formed in accordance with an embodiment of the present invention. Memory circuit 600 comprises a memory array 620 including a plurality of memory cells according to embodiments of the invention described herein organized into one or more rows and columns, a row circuit 630 (e.g., row on-pitch circuit) operatively coupled to one or more rows of memory cells in the memory array, a column circuit 640 (e.g., column on-pitch circuit) operatively coupled to one or more columns of memory cells in the memory array, and a control circuit 650 (e.g., processor). Typically, the memory array 620 is arranged such that one memory cell is located at each intersection of a row with a column, and is coupled to the intersecting row and column. Therefore, there is preferably a plurality of memory cells coupled to each column and to each row in the memory array 620. It is to be understood, however, that the invention is not limited to any particular organization of the memory cells therein.

The column circuit 640 preferably comprises one or more column address decoders, sense amplifiers and, optionally, column multiplexers. Each sense amplifier is coupled to at least one column to detect and amplify the data signal stored within a given memory cell coupled to that column. The column multiplexer in column circuit 640, if employed, is operative to allow a single sense amplifier to be connected to a plurality of columns of memory cells in the memory array 620. By way of example only, the sense amplifier may be coupled, through the column multiplexer, to the plurality of columns (e.g., eight).

The column multiplexer in column circuit 640 is coupled to an address input connection 611 adapted to receive an address signal supplied thereto. The address signal includes a column address and a row address. The column multiplexer selects, according to at least a first portion of the column address, which columns in the memory array 620 are coupled to which sense amplifiers in the column circuit 640 during a memory access, only one column being coupled to each sense amplifier at a given time. If the column multiplexer is not employed, each column is coupled directly to a corresponding sense amplifier in the column circuit 640. The column circuit 640 further optionally comprises an output selector circuit coupled to the output of the sense amplifiers and to a data-out output connection 614 adapted to provide data read from one or more memory cells in the memory array 620. The output selector circuit selects, according to at least a second portion of the column address, which sense amplifier outputs to couple to the data-out output connection 614. Column circuit 640 may also be coupled to a data-in input connection 613 adapted to receive a data input signal supplied thereto for writing data into one or more memory cells in the memory array 620.

The row circuit 630 preferably comprises one or more row address decoders and row drivers. The row address decoders are coupled to the address input connection 611 and to the row drivers in the row circuit 630. Each row driver is coupled to a row of memory cells within the memory array 620. Depending upon the row address, during a memory access, a given one of the row drivers in row circuit 630 will activate the row to which the given row driver is coupled.

The control circuit 650, which may comprise, for example, a processor, is coupled to a control input connection 612 adapted to receive a control signal supplied thereto, the row circuit 630 and the column circuit 640. The control circuit 650 functions, for example, to sequence internal memory operation. By way of example only, the control circuit 650 controls the sequence of address decoding, row activation, signal development, and sense amplifier amplification in the memory circuit 600. According to embodiments of the invention, the control circuit 650 preferably controls, as a function of the control signal supplied to the control input connection 612, the mode(s) of operation of the memory circuit 600, including, for example, when the memory array 620 is precharging, reading, writing, or in standby mode.

Optionally, the memory circuit 600 further comprises a voltage adjustment circuit 660 operative to supply a voltage to at least a portion of the memory circuit 600 during at least a portion of a time during which the memory is operated. The voltage adjustment circuit 660 is coupled to a power connection 615 adapted to receive a first supply voltage, which may be VDD (e.g., about one volt), a ground connection 616 adapted to receive a second supply voltage, which may be VSS or ground (e.g., zero volt), and the control circuit 650. The voltage adjustment circuit 660 may also be coupled to one or more other functional components within the memory circuit 600, such as, for example, memory array 620, row circuit 630 and/or column circuit 640, for selectively controlling the voltages supplied thereto. To this end, the voltage adjustment circuit 660 may comprise, for example, a programmable voltage supply operative to control an output voltage thereof as a function of at least one control signal applied thereto.

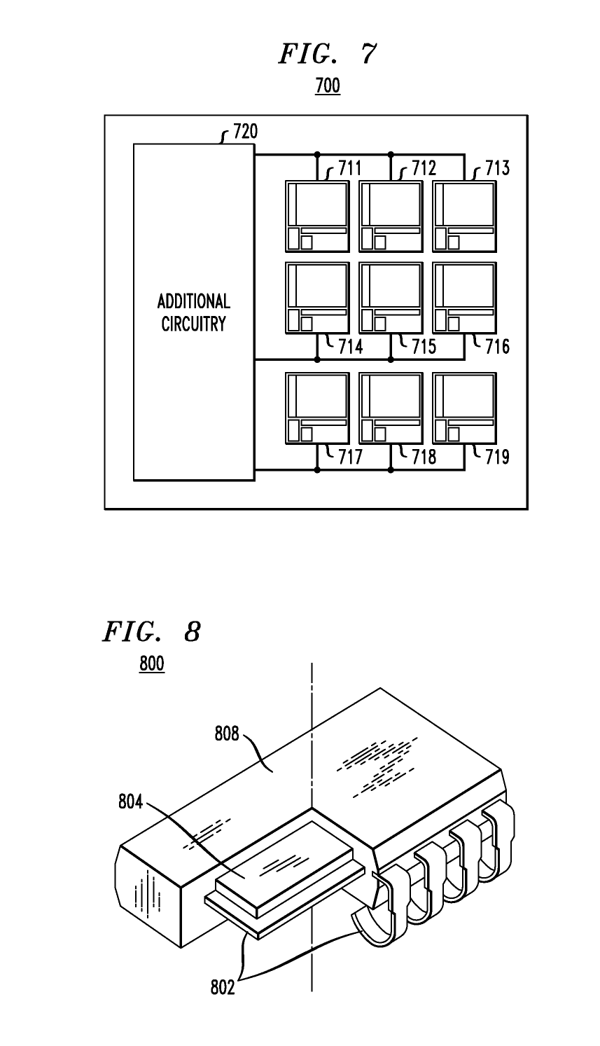

FIG. 7 is a block diagram depicting at least a portion of an exemplary IC 700 comprising a plurality of instances of the illustrative memory circuit 600 shown in FIG. 6, according to an embodiment of the present invention. Specifically, IC 700 comprises a plurality of memory instances, 711 through 719, and additional circuitry 720 coupled to the memory instances. The additional circuitry 720 preferably comprises, for example, a processor, a digital (e.g., logic) circuit, an analog circuit, an application specific integrated circuit, a gate array, etc., configured to perform, at least in part, one or more functions of the IC 700. At least one of the memory instances 711 through 719 comprises a memory circuit according to an embodiment of the invention, such as, for example, memory circuit 600 or another memory comprising 4T memory cells according to embodiments of the invention. The memory instances 711 through 719 are not necessarily identical to one another, although they could be.

Although embodiments of the present invention have been described herein comprising storage elements operative to store two data states (e.g., “0” and “1”), it is to be appreciated that the techniques of the invention can be similarly extended to a storage element operative to store more than two data states (e.g., three data states), as will become apparent to those skilled in the art given the teachings herein. A non-limiting example of a memory cell capable of storing more than two data states is described in U.S. Pat. No. 5,889,697, the disclosure of which is incorporated by reference herein in its entirety for all purposes. In such a storage element operative to store three or more data states, at least one of the data states is retained in the storage element by maintaining a first node of the storage element at a first voltage level by leakage current and by maintaining at least a second node of the storage element at a second voltage level by active current. Thus, as in the case of a memory cell operative to store two data states, the storage element operative to store three or more data states uses a combination of leakage and active currents for storing the data states therein.

At least a portion of the techniques of the present invention may be implemented in one or more integrated circuits. In forming integrated circuits, die are typically fabricated in a repeated pattern on a surface of a semiconductor wafer. Each of the die includes a memory described herein, and may include other structures or circuits. Individual die are cut or diced from the wafer, then packaged as integrated circuits. FIG. 8 is a partial sectional view depicting an exemplary packaged IC 800 comprising at least one memory circuit according to an embodiment of the invention, for example memory circuit 600 (FIG. 6), memory instances 711-719 (FIG. 7), and/or at least one memory cell comprising a 4T memory cell according to embodiments of the invention described herein. The packaged IC 800 comprises a leadframe 802, a die 804 attached to the leadframe, the die including a memory circuit in accordance with an embodiment of the invention, and a plastic encapsulation mold 808. One skilled in the art would know how to dice wafers and package die to produce integrated circuits. Integrated circuits so manufactured are considered part of this invention.

An IC in accordance with embodiments of the present invention can be employed in any application and/or electronic system which utilizes memory (e.g., embedded or discrete memory). Suitable systems for implementing embodiments of the invention may include, but are not limited to, personal computers, communication networks, electronic commerce systems, portable communications devices (e.g., cell phones), solid-state media storage devices, etc. Systems incorporating such integrated circuits are considered part of this invention. Given the teachings of the invention provided herein, one of ordinary skill in the art will be able to contemplate other implementations and applications of the techniques of the invention.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. A memory circuit including at least one memory cell, the at least one memory cell comprising:
a storage element comprising a transistor and an inverter, the inverter having an input coupled to a first source/drain of the transistor at a first node and having an output coupled to a gate of the transistor at a second node, the transistor having a second source/drain coupled to a first voltage supply of the memory circuit; and
a switching element coupled to the storage element at the first node and being operative to selectively access the storage element as a function of a control signal supplied to a control input of the switching element;
wherein the storage element is operative to store at least a first data state and a second data state, wherein the first data state is retained in the storage element by maintaining the first node of the storage element at a first voltage level by leakage current and by maintaining the second node at a second voltage level by active current, and wherein the second data state is retained in the storage element by maintaining the first node of the storage element at the second voltage level by active current and by maintaining the second node at the first voltage level by active current.

2. The memory circuit of claim 1, wherein the first data state is retained in the storage element by maintaining the first node of the storage element at the first voltage level by leakage current through the switching element and by maintaining the second node at the second voltage level by active current through the inverter, and wherein the second data state is retained in the storage element by maintaining the first node of the storage element at the second voltage level by active current through the transistor and by maintaining the second node at the first voltage level by active current through the inverter.

3. The memory circuit of claim 1, wherein the switching element comprises a transistor having a first source/drain coupled to a corresponding bitline in the memory circuit, a second source/drain coupled to the storage element at the first node, and a gate coupled to a corresponding wordline in the memory circuit and forming the control input of the switching element.

4. The memory circuit of claim 3, further comprising a programmable voltage source coupled to the transistor and operative to control a back-gate bias voltage on the transistor for controlling leakage current through the transistor when the transistor is biased in an off state.

5. The memory circuit of claim 1, wherein the storage element comprises:
a first NMOS transistor including a first source/drain coupled to the first voltage supply of the memory circuit, a second source/drain connected to the second node, and a gate connected to the first node;
a second NMOS transistor including a first source/drain coupled to the first voltage supply, a second source/drain connected to the first node, and a gate connected to the second node; and
a PMOS transistor including a first source/drain coupled to a second voltage supply of the memory circuit, a second source/drain connected to the second node, and a gate connected to the first node.

6. The memory circuit of claim 5, wherein the first data state is retained in the storage element by maintaining the first node at the first voltage by leakage current through the switching element and by maintaining the second node at the second voltage level by active current through the first NMOS transistor, and wherein the second data state is retained in the storage element by maintaining the first node at the second voltage level by active current through the second NMOS transistor and by maintaining the second node at the first voltage level by active current through the PMOS transistor.

7. The memory circuit of claim 5, wherein the switching element is inactive when the first NMOS transistor is biased in an on state.

8. The memory circuit of claim 5, wherein the second NMOS transistor is biased in an on state when the PMOS transistor is biased in an on state.

9. The memory circuit of claim 1, wherein the storage element comprises:
a first PMOS transistor including a first source/drain coupled to the first voltage supply of the memory circuit, a second source/drain connected to the second node, and a gate connected to the first node;
a second PMOS transistor including a first source/drain coupled to the first voltage supply, a second source/drain connected to the first node, and a gate connected to the second node; and
an NMOS transistor including a first source/drain coupled to a second voltage supply of the memory circuit, a second source/drain connected to the second node, and a gate connected to the first node.

10. The memory circuit of claim 9, wherein the first data state is retained in the storage element by maintaining the first node at the first voltage level by leakage current through the switching element and by maintaining the second node at the second voltage level by active current through the first PMOS transistor, and wherein the second data state is retained in the storage element by maintaining the first node at the second voltage level by active current through the second PMOS transistor and by maintaining the second node at the first voltage level by active current through the NMOS transistor.

11. The memory circuit of claim 1, further comprising a bitline coupled to the switching element at a third node, the switching element comprising a PMOS transistor, wherein the bitline is set to a precharge voltage level during a precharge phase of the memory circuit, the precharge voltage level being greater than or equal to the second voltage level, and wherein the first data state corresponds to a first node voltage on the first node being greater than a second node voltage on the second node.

12. The memory circuit of claim 1, further comprising a bitline coupled to the switching element at a third node, the switching element comprising an NMOS transistor, wherein the bitline is set to a precharge voltage level during a precharge phase of the memory circuit, the precharge voltage level being less than or equal to the first voltage level, and wherein the first data state corresponds to a first node voltage on the first node being less than a second node voltage on the second node.

13. The memory circuit of claim 1, further comprising a bitline coupled to the switching element at a third node, the switching element comprising an NMOS transistor, wherein the bitline is set to a precharge voltage level during a precharge phase of the memory circuit, the precharge voltage level being greater than or equal to the second voltage level, and wherein the first data state corresponds to a first node voltage on the first node being greater than a second node voltage on the second node.

14. The memory circuit of claim 1, further comprising a bitline coupled to the switching element at a third node, the switching element comprising a PMOS transistor, wherein the bitline is set to a precharge voltage level during a precharge phase of the memory circuit, the precharge voltage level being less than or equal to the first voltage level, and wherein the first data state corresponds to a first node voltage on the first node being less than a second node voltage on the second node.

15. The memory circuit of claim 1, wherein the switching element comprises a PMOS transistor including a first source/drain coupled to a corresponding bitline in the memory circuit, a second source/drain coupled to the first node, a gate coupled to the control input of the switching element, and a back-gate contact coupled to a second voltage supply providing a back-gate voltage, wherein the back-gate voltage is lower during at least one of a store mode, a precharge phase and a hold phase than during at least one of a write mode and a read mode in the memory circuit.

16. The memory circuit of claim 1, wherein the switching element comprises an NMOS transistor comprising a first source/drain coupled to a corresponding bitline in the memory circuit, a second source/drain coupled to the first node, a gate coupled to the control input of the switching element, and a back-gate contact coupled to a second voltage supply providing a back-gate voltage, wherein the back-gate voltage is higher during at least one of a store mode, a precharge phase and a hold phase than during at least one of a write mode and a read mode in the memory circuit.

17. The memory of claim 1, wherein the switching element comprises a switching transistor including a first source/drain coupled to a corresponding bitline in the memory circuit, a second source/drain connected to the storage element at the first node, a first parasitic diode formed at a junction between the first source/drain and a chancel region in the switching transistor, and a second parasitic diode formed at a junction between the second source/drain and the channel region, wherein the leakage current through the switching transistor comprises at least one of: (i) leakage current between the first source/drain and the second source/drain; (ii) leakage current through the first parasitic diode; and (iii) leakage current through the second parasitic diode.

18. The memory circuit of claim 1, wherein the storage element is operative to store at least three data states therein, at least one of the data states being retained in the storage element by maintaining the first node of the storage element at a first voltage level by leakage current and by maintaining the second node at a second voltage level by active current.

19. An integrated circuit including an embedded memory circuit, the memory circuit including at least one memory cell comprising:
a storage element comprising a transistor and an inverter, the inverter having an input coupled to a first source/drain of the transistor at a first node and having an output coupled to a gate of the transistor at a second node, the transistor having a second source/drain coupled to a voltage supply of the memory circuit; and
a switching element coupled to the storage element at the first node and being operative to selectively access the storage element as a function of a control signal supplied to a control input of the switching element;
wherein the storage element is operative to store at least a first data state and a second data state, wherein the first data state is retained in the storage element by maintaining the first node of the storage element at a first voltage level by leakage current and by maintaining the second node at a second voltage level by active current, and wherein the second data state is retained in the storage element by maintaining the first node of the storage element at the second voltage level by active current and by maintaining the second node at the first voltage level by active current.

20. An electronic system, comprising:
at least one integrated circuit including a memory circuit comprising at least one memory cell, the at least one memory cell comprising:
a storage element comprising a transistor and an inverter, the inverter having an input coupled to a first source/drain of the transistor at a first node and having an output coupled to a gate of the transistor at a second node, the transistor having a second source/drain coupled to a first voltage supply of the at least one memory circuit; and
a switching element coupled to the storage element at the first node and being operative to selectively access the storage element as a function of a control signal supplied to a control input of the switching element;
wherein the storage element is operative to store at least a first data state and a second data state, wherein the first data state is retained in the storage element by maintaining the first node of the storage element at a first voltage level by leakage current and by maintaining the second node at a second voltage level by active current, and wherein the second data state is retained in the storage element by maintaining the first node of the storage element at the second voltage level by active current and by maintaining the second node at the first voltage level by active current.
